(19) United States
(12) Patent Application Publication
(10) Pub. No.: US 2020/0150327 A1
(43) Pub. Date: May 14, 2020

(54) DISPLAY PANEL AND DISPLAY DEVICE

(71) Applicant: WUHAN CHINA STAR OPTOELECTRONICS TECHNOLOGY CO., LTD., Wuhan, Hubei (CN)

(72) Inventors: Chaoqun YANG, Wuhan, Hubei (CN); Changchih HUANG, Wuhan, Hubei (CN)

(21) Appl. No.: 16/335,250

(22) PCT Filed: Jan. 8, 2019
(86) PCT No.: PCT/CN2019/070802

§ 371 Date: Mar. 21, 2019

(30) Foreign Application Priority Data
Oct. 30, 2018 (CN) 201811277841.1

(51) Int. Cl. G02B 5/20; H01L 27/32; H01L 51/52

(52) U.S. Cl. CPC G02B 5/201; H01L 51/5284; H01L 27/322

(57) ABSTRACT

A display panel includes a substrate. A color film layer is formed on the substrate. The color film layer includes first color resistances and second color resistances, first color quantum dots are disposed in the first color resistances, and second color quantum dots are disposed in the second color resistances. The color film layer further includes reflecting color resistances, the reflecting color resistances are formed between the first color resistances and the second color resistances. Reflectivities of contact surfaces between the reflecting color resistances and the first color resistances and between the reflecting color resistances and the second color resistances are greater than 70%, to make first color incident light emitted by the quantum dots of the first color resistances and second color incident light emitted by the quantum dots of the second color resistances to be reflected back to color resistances to excite the quantum dots to illuminate.

### CROSS REFERENCE TO RELATED APPLICATION

This application claims the priority of International Application No. PCT/CN2019/070802 filed on 2019 Jan. 8, which claims priority to Chinese Application No. 201811277841.1, filed on 2018 Oct. 30. The entire disclosures of each of the above applications are incorporated herein by reference.

### BACKGROUND OF INVENTION

### Field of Invention

The present application relates to displays, and particularly to a display panel used in organic light emitting diode (OLED) display devices and liquid crystal display (LCD) devices.

### Description of Prior Art

As known, quantum dot (QD) materials have a relatively wide absorption peak and a relatively narrow emission peak for having good performance in purity of color display, which improve display effect of display devices when they are applied to the display devices. For example, they are used in the liquid crystal displays (LCDs) to improve color gamut of the display devices and to increase competitiveness of the display devices.

However, there are a lot of problems to be solved in a concrete implementation. One of them is that a problem of mixing color and a low light utilization rate of a quantum dot color resistance.

The mixing color problem is that, referring to FIG. 2, a plurality of quantum dots with different colors is arranged along a row on an over coating layer 102 of a substrate 100 of a display device, each color resistance emits one color light which is a red, green, or blue light. Light emitted between two adjacent color resistances, due to differences of emitting angles, will enter into an adjacent color resistance. A black matrix layer formed on a color resistance 110 has a resistance function, but as shown by the arrow lines of the figure, light may enter into the adjacent color resistance 110 to make the mixing color problem of two color light.

Correspondingly, light excited from the quantum dots of the color resistances emits from the color resistances, cannot go back to the color resistances, and cannot excite the quantum dots of the color resistances to make them not to be excited and to make a low light utilization.

Therefore, it is necessary to make a new display panel to overcome defects of prior art.

### SUMMARY OF INVENTION

The application mainly provides a display panel to solve a mixing color problem and a low light utilization of prior art.

For the above-mentioned objective, the present disclosure employs the following technical schemes.

A display panel includes a substrate. A color film layer is formed on the substrate. The color film layer includes first color resistances and second color resistances, wherein a plurality of first color quantum dots are disposed in the first color resistances, and a plurality of second color quantum dots are disposed in the second color resistances. The color film layer further includes reflecting color resistances, the reflecting color resistances are formed between the first color resistances and the second color resistances. Reflectivities of contact surfaces between the reflecting color resistances and the first color resistances and between the reflecting color resistances and the second color resistances are greater than 70%.

Further, in one embodiment, optical densities of contact surfaces between the reflecting color resistances and the glass layer are greater than 3/μm.

Further, in one embodiment, thicknesses of the reflecting color resistances range from 3 to 8 μm.

Further, in one embodiment, top surfaces of the reflecting color resistances are higher than top surfaces of the first color resistances and top surfaces of the second color resistances along a vertical direction, and bottom surfaces of the reflecting color resistances are lower than bottom surfaces of the first color resistances and bottom surfaces of the second color resistances along the vertical direction.

Further, in one embodiment, the color film layer further includes a plurality of third color resistances, the reflecting color resistances are further formed between the third color resistances and the second color resistances, a plurality of third color quantum dots are disposed in the third color resistances.

Further, in one embodiment, the color film layer further includes a plurality of third color resistances, the reflecting color resistances are formed among the third color resistances, the second color resistances, and the first color resistances.

Further, in one embodiment, a first color of the first color resistances is red, a second color of the second color resistances is green, and a third color of the third color resistances is blue.

Further, in one embodiment, blue light shading layers are formed on the first color resistances and the second color resistances.

Further, in one embodiment, a black matrix (BM) layer is formed between the top surfaces of the reflecting color resistances and the glass layer.

Further, a display device is provided in this application and includes the display panel of this application.

The beneficial effect of this invention is: this application relates to a display panel, a plurality of reflecting color resistances with high light blocking ratio and high reflectivity are formed between the color resistances. The reflecting color resistances have high light blocking ratio and high reflectivity for incident light to make the incident light be reflected back to the color resistances and to excite the quantum dots to illuminate, thereby to improve light utilization and to reduce power consumption, while, incident light which is not reflected back to the color resistances are blocked by the reflecting color resistances to avoid them penetrating through the reflective color resistances to adjacent color resistances with different colors to cause color mixing problems.

### BRIEF DESCRIPTION OF DRAWINGS

The accompanying figures to be used in the description of embodiments of the present disclosure or prior art will be described in brief to more clearly illustrate the technical solutions of the embodiments or the prior art. The accompanying figures described below are only part of the embodiments of the present disclosure, from which figures those skilled in the art can derive further figures without making any inventive efforts.

FIG. 1 is a structural view of a display panel of one exemplary embodiment according to the present disclosure.

FIG. 2 is a structural view of a display panel of prior art.

### DETAILED DESCRIPTION OF PREFERRED EMBODIMENTS

The technical solutions of a display panel and a display device thereof according to the present invention will be further described in detail below with reference to the accompanying drawings and embodiments.

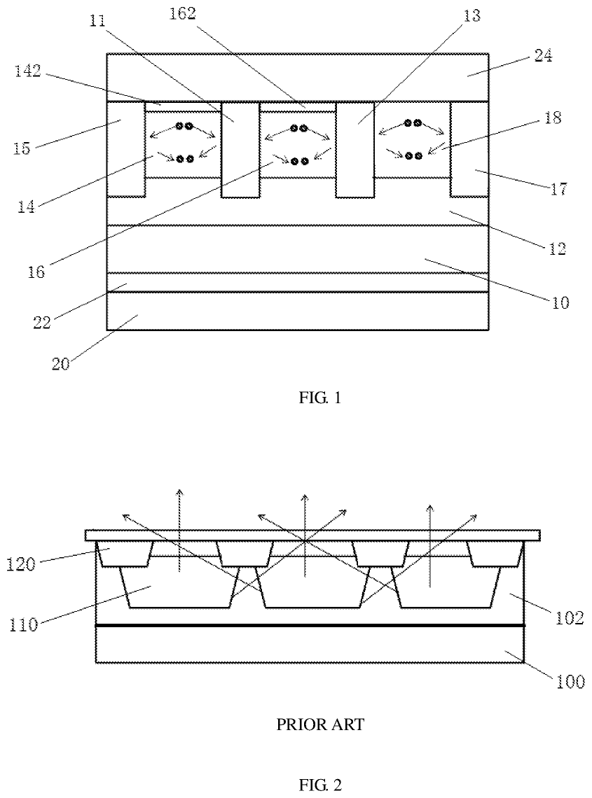

Referring to FIG. 1, a display panel is provided by the present application, which includes a blue light backlight module 20, a polaroid 22, a substrate 10, an OC layer 12, a color film layer and a glass layer 24 formed sequentially.

The color film layer includes first color resistances 14, second color resistances 16, and third color resistances 18. A plurality of quantum dots corresponding to colors of the color resistances are disposed in the color resistances to be excited and to illuminate, for example, colors can be red, green, and blue.

Further, each reflecting color resistances is formed between two adjacent color resistances to separate the two adjacent color resistances along a vertical direction. As shown in the picture, three color resistances are formed among a first reflecting color resistance 11, a second reflecting color resistance 13, a third reflecting color resistance 15, and a fourth reflecting color resistance 17.

Detailed, in a producing process of the color film layer, materials of the reflecting color resistances are coated, the reflecting color resistances can be negative photoresists made of macromolecule, such as resin materials, and include and not limit to phenolic resin and polymer resin containing unsatisfied vinyl or methyl vinyl. Further, the selected materials can include metal particles, such as aluminium metallicum, a color of the reflecting color resistances containing them is close to white.

Then a vacuum process and a pre bake process are employed to remove excess solvent, and an exposure and development are employed to make patterns of a mask transfer to a surface of the negative photoresist to finally form the reflecting color resistances separated from each other.

The reflecting color resistances separated from each other are made of same materials and not limited. In one embodiment, the reflecting color resistances are made of same materials with a high light blocking ratio and high reflectivity. The optical density (OD) can be greater than 3/μm, the OD is preferably 4/μm or 4.24/μm. The minimum requirement for high reflectance can be greater than 70%, and is preferably greater than 80%. Further, thicknesses of the reflecting color resistances can range from 3 to 8 μm, the selected thicknesses can be determined as needed, and is not limited.

Further, after the reflecting color resistances are formed, the first color resistances, the second color resistances and the third color resistances are formed sequentially between the two reflecting color resistances. The materials of the first color resistances, the second color resistances and the third color resistances are different, so they are formed sequentially, for example, they are R type color resistances, G type color resistances, and B type color resistances, so need to be formed sequentially.

Taking a manufacturing process of the first color resistances as an example, materials of them are coated, the materials can be negative photoresists, generally as resin materials; then after a vacuum process and a prebake process are employed to remove excess solvent, an exposure and development are employed to form the first color resistances. Manufacturing processes of the second color resistances and the third color resistances are similar to the manufacturing process of the first color resistances in order to avoid unnecessary repetition, it is not to be repeated here.

Further, in order to ensure that the reflecting color resistances can reflect an incident light of various angles emitted by the adjacent color resistances, the reflecting color resistances are preferably higher and lower than the adjacent color resistances in the vertical direction. Referring to the picture, the third reflecting color resistance 15 and the first reflecting color resistance 11 are formed around or at two sides of the first color resistance 14, top surfaces of the two reflecting color resistances 11, 15 are higher than the first color resistance 14 in the vertical direction, and bottom surfaces are lower than a bottom surface of the first color resistance 14. The second color resistance 16 and the third color resistance 18 are formed similarly as the above, in order to avoid unnecessary repetition, it is not to be repeated here.

In use, blue light emitted from the blue light backlight module 20 emits upward and penetrates through the polaroid 22, the substrate 10 and the OC layer 12 into the color resistances to excite the quantum dots therein to illuminate. In this embodiment, the quantum dots of the first color resistances 14 are excited to emit red light, the quantum dots of the second color resistances 16 are excited to emit green light, and the quantum dots of the third color resistances 18 are excited to emit blue light. Correspondingly, blue light shading layers 142, 162 are formed on the first color resistances 14 and the second color resistances 16 to shade needless blue light and to prevent them from emitting from the color resistances to create unnecessary defects.

As shown in the picture, each color resistance is formed around by the reflecting color resistances, so the quantum dots of the color resistances are excited to emit light which will be reflected back to the color resistances by the reflecting color resistances and to excite the quantum dots to illuminate, thereby to improve light utilization and to reduce power consumption, while, incident light which is not reflected back to the color resistances is blocked by the reflecting color resistances to prevent them from penetrating through the reflective color resistances to adjacent color resistances with different colors to cause color mixing problems.

Further, in order to make a good display performance, a black matrix (BM) layer can be formed between touching surfaces of the reflecting color resistances and the glass layer 24 to prevent accident light coming from outside of the glass layer 24 from penetrating through the glass layer 24 to be reflected by the reflecting color resistances, or a roughening process is employed at top surfaces of the reflecting color resistances to reduce reflecting performance.

The technical scope of the present invention is not limited to the above description of the contents. Any person who skilled in the art may deform and modify the embodiment of the present invention within the spirit and scope of the appended claims, but these deformation and modification belong to the protection scope of the present invention.

What is claimed is:

1. A display panel, comprising a substrate, wherein a color film layer and a glass layer are formed on the substrate, the color film layer comprises first color resistances and second color resistances, wherein a plurality of first color quantum dots are disposed in the first color resistances, and a plurality of second color quantum dots are disposed in the second color resistances;
wherein the color film layer further comprises reflecting color resistances, the reflecting color resistances are formed between the first color resistances and the second color resistances; wherein reflectivities of contact surfaces between the reflecting color resistances and the first color resistances and between the reflecting color resistances and the second color resistances are greater than 70%.

2. The display panel of claim 1, wherein optical densities of contact surfaces between the reflecting color resistances and the glass layer are greater than 3/μm.

3. The display panel of claim 1, wherein thicknesses of the reflecting color resistances range from 3 to 8 μm.

4. The display panel of claim 1, wherein top surfaces of the reflecting color resistances are higher than top surfaces of the first color resistances and top surfaces of the second color resistances along a vertical direction, and bottom surfaces of the reflecting color resistances are lower than bottom surfaces of the first color resistances and bottom surfaces of the second color resistances along the vertical direction.

5. The display panel of claim 1, wherein the color film layer further comprises a plurality of third color resistances, the reflecting color resistances are further formed between the third color resistances and the second color resistances, a plurality of third color quantum dots are disposed in the third color resistances.

6. The display panel of claim 1, wherein the color film layer further comprises a plurality of third color resistances, the reflecting color resistances are formed among the third color resistances, the second color resistances, and the first color resistances.

7. The display panel of claim 6, wherein a first color of the first color resistances is red, a second color of the second color resistances is green, and a third color of the third color resistances is blue.

8. The display panel of claim 7, wherein blue light shading layers are formed on the first color resistances and the second color resistances.

9. The display panel of claim 1, wherein a black matrix (BM) layer is formed between the top surfaces of the reflecting color resistances and the glass layer.

10. A display device, comprising the display panel of claim 1.
